(19) United States
(12) Patent Application Publication
(10) Pub. No.: US 2025/0223221 A1
(43) Pub. Date: Jul. 10, 2025

(54) GLASS SUBSTRATE

(71) Applicant: AGC Inc., Tokyo (JP)

(72) Inventors: Yuha KOBAYASHI, Tokyo (JP); Kaede Okamoto, Tokyo (JP)

(73) Assignee: AGC Inc., Tokyo (JP)

(21) Appl. No.: 19/096,547

(22) Filed: Mar. 31, 2025

Related U.S. Application Data
(63) Continuation of application No. PCT/JP2023/037202, filed on Oct. 13, 2023.

(30) Foreign Application Priority Data
Oct. 21, 2022 (JP) 2022-169457

(51) Int. Cl. C03C 23/00

(52) U.S. Cl. CPC C03C 23/0025; C03C 2204/08

(57) ABSTRACT

To suppress a fracture at the time of laser machining. A glass substrate has a surface on which a mark is provided, and a parameter (y) thereof defined by an expression (1) is smaller than 1.4.

### CROSS-REFERENCE TO RELATED APPLICATION(S)

This application is a continuation of International Application No. PCT/JP2023/037202, filed on Oct. 13, 2023 which claims the benefit of priority of the prior Japanese Patent Application No. 2022-169457, filed on Oct. 21, 2022, the entire contents of which are incorporated herein by reference.

### BACKGROUND OF THE INVENTION

### 1. Field of the Invention

The present invention relates to a glass substrate.

### 2. Description of the Related Art

A glass substrate may be used as a member for supporting a semiconductor device during a manufacturing process for a semiconductor device. For example, as disclosed in WO 2018/150759 and Japanese Patent Application Laid-open No. 2019-131462, a mark may be formed on a surface of such a glass substrate by irradiating the surface of the glass substrate with laser light. A use of glass as a substrate of a semiconductor device and cover glass for an image sensor has been widened, and a mark for identification is typically required on a glass surface of glass used for a semiconductor process.

However, the glass substrate may have high fragility, so that a fracture may be caused by stress concentration around the mark formed on the surface, residual stress, or a microcrack. Thus, there is a demand for suppressing a fracture on the glass substrate.

The present invention is made in view of the problem described above, and aims at providing a glass substrate that can suppress a fracture.

### SUMMARY OF THE INVENTION

It is an object of the present invention to at least partially solve the problems in the conventional technology.

The glass substrate of the present disclosure has a surface on which a mark is provided, wherein a parameter y defined by the following expression (1) is smaller than 1.4.

$$y = 0.0 \; 21 \cdot C - 0.0034 \cdot Tg - 0.012 \cdot ρ + 0.02 \cdot E - 2.814 \cdot λ - 0.433 \cdot Ra + 4.372 \qquad ( 1 )$$

C is an average thermal expansion coefficient (ppm/° C.) of the glass substrate at 50° C. to 200° C., Tg is a glass transition temperature (° C.) of the glass substrate, p is a density (g/cm³) of the glass substrate, E is a Young's modulus (GPa) of the glass substrate, A is a thermal conductivity (W/m.° C.) of the glass substrate, and Ra is an arithmetic average roughness (nm) defined in JIS B 0601:2001 of the surface of the glass substrate.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic diagram of a glass substrate according to an embodiment;

FIG. 2 is a schematic diagram of an example of a mark;

FIG. 3 is a schematic enlarged view of a portion of the glass substrate where a dot is formed; and

FIG. 4 is an A-A cross-sectional view of FIG. 3.

### DETAILED DESCRIPTION OF THE PREFERRED EMBODIMENTS

The following describes a preferred embodiment of the present invention in detail with reference to the attached drawings. The present invention is not limited to the embodiment, and in a case in which there are a plurality of embodiments, the embodiments may be combined with each other. Numerical values encompass rounded numerical values.

### Glass Substrate

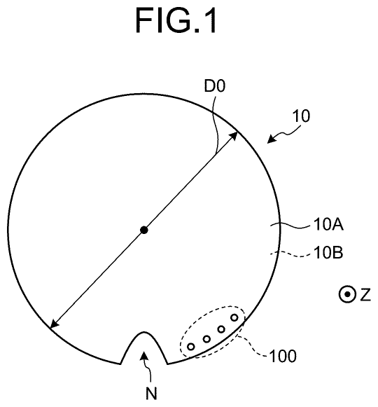

FIG. 1 is a schematic diagram of a glass substrate according to the present embodiment. A glass substrate 10 according to the present embodiment is used as a glass substrate for manufacturing a semiconductor package, and can be said to be a glass substrate for supporting a semiconductor device. More specifically, the glass substrate 10 is a support glass substrate for manufacture using a Fan Out Wafer Level Package (FOWLP) technique. For example, in a case in which the glass substrate 10 has a rectangular shape, the glass substrate 10 is a support glass substrate for manufacturing a Fan Out Panel Level Package (FOPLP). However, a use of the glass substrate 10 is not limited to supporting the semiconductor device and manufacturing the FOWLP or the FOPLP, and is optional. The glass substrate 10 may be a glass substrate used for supporting an optional member. Additionally, the glass substrate 10 may be cover glass for an image sensor, or glass or crystallized glass processed to be an optional product such as a substrate for a semiconductor device.

As illustrated in FIG. 1, the glass substrate 10 is a plate-shaped member including a surface 10A (one surface) as a principal plane on one side and a surface 10B (another surface) as a principal plane on the opposite side of the surface 10A. The glass substrate 10 has a disc shape, which is a circular shape, in a plan view, that is, when viewed from a direction orthogonal to the surface 10A. In other words, the glass substrate 10 has a wafer shape. Alternatively, a notch part N may be formed on an outer peripheral surface of the glass substrate 10, and the glass substrate 10 may have a shape obtained by partially notching an outer circumference of the circular shape. However, the shape of the glass substrate 10 is not limited to the disc shape and may be an optional shape. For example, the glass substrate 10 may be a plate having a polygonal shape such as a rectangular plate shape. Additionally, the notch part N is not an essential configuration, so that the notch part N is not necessarily formed on the glass substrate 10. For example, in a case in which the glass substrate 10 has a circular plate shape as described later, the notch part N is preferably formed. Hereinafter, a direction orthogonal to the surface 10A is referred to as a Z-direction. It can also be said that the Z-direction is a thickness direction of the glass substrate 10.

### Diameter of Glass Substrate

A diameter D0 of the glass substrate 10 is preferably equal to or larger than 150 mm and equal to or smaller than 1000 mm, preferably equal to or larger than 150 mm and equal to or smaller than 700 mm, more preferably equal to or larger than 150 mm and equal to or smaller than 600 mm, and even more preferably equal to or larger than 150 mm and equal to or smaller than 450 mm. By causing the diameter D0 to fall within this range, a member such as a semiconductor device can be appropriately supported. The diameter D0 indicates a diameter in a case in which the glass substrate 10 has a circular shape. However, in a case in which the glass substrate 10 does not have the circular shape, the diameter D0 may indicate a maximum value of a distance between optional two points on an outer peripheral edge of the glass substrate 10.

In a case in which the glass substrate 10 has a disc shape, the diameter D0 is preferably equal to or smaller than 450 mm, and more preferably equal to or smaller than 300 mm. In a case in which the glass substrate 10 has a rectangular plate shape, the diameter D0 (that is, a maximum value of a distance between optional two points on an outer peripheral edge) is preferably equal to or larger than 300 mm and equal to or smaller than 1000 mm.

### Thickness of Glass Substrate

A thickness of the glass substrate 10, that is, a length in the Z-direction between the surface 10A and the surface 10B, is preferably equal to or smaller than 2 mm, more preferably equal to or larger than 0.3 mm and equal to or smaller than 2.0 mm, even more preferably equal to or larger than 0.5 mm and equal to or smaller than 2.0 mm, even more preferably equal to or larger than 0.5 mm and equal to or smaller than 1.8 mm, and yet more preferably equal to or larger than 0.6 mm and equal to or smaller than 1.5 mm. By causing the thickness of the glass substrate 10 to be equal to or smaller than 2 mm, it is possible to suppress handling difficulty due to an increase in weight. By causing the thickness to be larger than 0.3 mm, it is possible to increase rigidity at the time of being used as a supporting member, and suppress warpage of glass or a semiconductor device.

In a case in which the glass substrate 10 has a disc shape, the thickness is preferably equal to or larger than 0.3 mm and equal to or smaller than 2.0 mm, and in a case in which the glass substrate 10 has a rectangular plate shape, the thickness is preferably equal to or larger than 0.5 mm and equal to or smaller than 2.0 mm.

A deviation of the thickness of the glass substrate 10 is preferably equal to or smaller than 10 μm, more preferably equal to or smaller than 5 μm, even more preferably equal to or smaller than 3 μm, and yet more preferably equal to or smaller than 1 μm. By causing the deviation of the thickness to fall within this range, the thickness of the glass substrate 10 approaches a uniform thickness, the semiconductor device can be appropriately manufactured, and stable processing can be performed in forming the mark. The deviation of the thickness indicates a difference between a maximum value and a minimum value of the thickness at respective positions (respective coordinates) on a plane along the surface of the glass substrate 10. For example, the thickness may be calculated for each position (coordinates) on the plane along the surface of the glass substrate 10, and a difference between the maximum value and the minimum value of the thickness at the respective positions may be assumed to be the deviation of the thickness.

A Local Thickness Variation (LTV) in 50 mm×50 mm of the glass substrate 10 is preferably equal to or smaller than 1 μm, and more preferably equal to or smaller than 0.5 μm. The LTV in 50 mm×50 mm indicates a difference between the maximum value and the minimum value of the thickness in a unit region of 50 mm×50 mm at an optional position on the glass substrate 10. In other words, the deviation of the thickness is a difference between the maximum value and the minimum value of the thickness in the entire region of the glass substrate 10, but the LTV indicates a difference between the maximum value and the minimum value of the thickness in the unit region of the glass substrate 10.

### Mark

On the surface 10A of the glass substrate 10, a mark 100 is formed. The mark 100 may be, for example, an identifier constituted of at least one of a numeral, a character, a two-dimensional code, and a figure. The number of numerals, characters, two-dimensional codes, and figures may be one or multiple. It can be said that the mark 100 as the identifier is a mark for identifying the glass substrate 10. The mark 100 as the identifier can be used for identifying and managing the glass substrate 10, for example.

The mark 100 is not limited to the identifier for identifying the glass substrate 10, but may be an alignment mark, for example. The alignment mark is, for example, a mark for positioning the glass substrate 10, and can be used for aligning a position or a direction of the glass substrate 10 at the time of handling thereof or performing processing such as cutting, chamfering, and bonding thereon. The alignment mark may be a mark for determining orientation of the glass. That is, at the time of laminating a device and the like on the glass substrate, the mark 100 may be formed on an opposite surface of a surface on which the device and the like are laminated corresponding to variation of warpage at the time of manufacturing the device and the like.

Hereinafter, each one of a numeral, a character, and a figure constituting the mark 100 is referred to as a mark element 102. That is, the mark 100 is constituted of a plurality of the mark elements 102. However, the mark 100 may be constituted of one mark element 102.

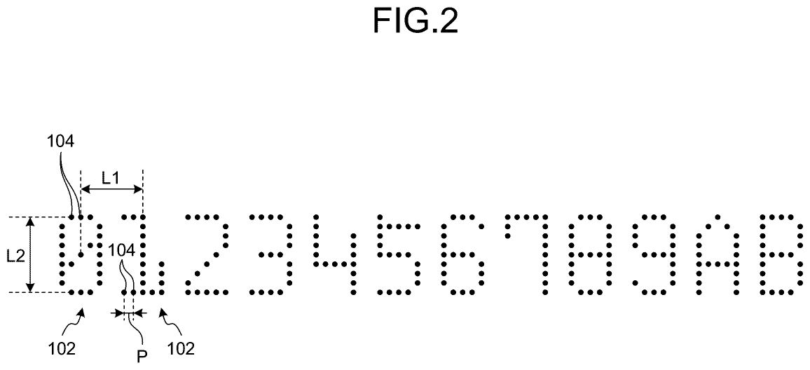

FIG. 2 is a schematic diagram of an example of the mark. In the example of FIG. 2, the mark 100 is illustrated as an identifier constituted of 12 mark elements 102 linearly arranged in a line. However, an aspect of the mark 100 is not limited thereto. For example, the mark 100 may have a configuration in which the mark elements 102 are non-linearly arranged. Alternatively, the mark 100 may have a configuration in which two or more lines of the mark elements 102 are linearly or non-linearly arranged.

Dimensions of the entire mark 100 are not particularly limited. For example, in a case of linear arrangement of the mark elements 102 as illustrated in FIG. 2, a space L1 between characters may fall within a range of 1.420±0.025 mm, and a vertical length L2 may be 1.624±0.025 mm. In a case in which the mark 100 is constituted of the mark elements 102 that are non-linearly arranged, the space L1 between the characters and the vertical length L2 of the mark 100 are respectively defined as, assuming a minimum rectangle including the mark 100, a length of a first side and a length of a second side of the minimum rectangle. The space L1 between the characters is a distance between the center of the mark element 102 and the center of the mark element 102 that is adjacent to the former mark element 102 in a lateral direction, and the vertical length L2 indicates a distance in a vertical direction between the center of a dot 104 closest to one side in the vertical direction of the mark element 102 and the center of the dot 104 closest to another side in the vertical direction.

The mark element 102 (mark 100) is constituted of a plurality of the dots 104. In other words, one mark element 102 or mark 100 is formed of the dots 104. In the present embodiment, the dots 104 do not overlap with each other, and are formed to be separated from each other. A pitch P between the adjacent dots 104 is defined by SEMI AUX015-1106 SEMI OCR CHARACTER OUTLINES or SEMI-T7-0303, and defined based on types of a font and a two-dimensional code. The pitch P indicates a distance between the center of one dot 104 and the center of the dot 104 adjacent to the former dot 104 in a direction along the surface 10A.

The dot 104 is formed by machining such as laser machining or sand blasting, chemical etching, printing, and the like. Particularly, in a case of being formed by laser machining, the mark element 102 may be constituted of a plurality of laser irradiation traces. A size of the laser irradiation trace or a pitch between the irradiation traces is determined based on a configuration of an optical system of a laser machining device.

### Dot

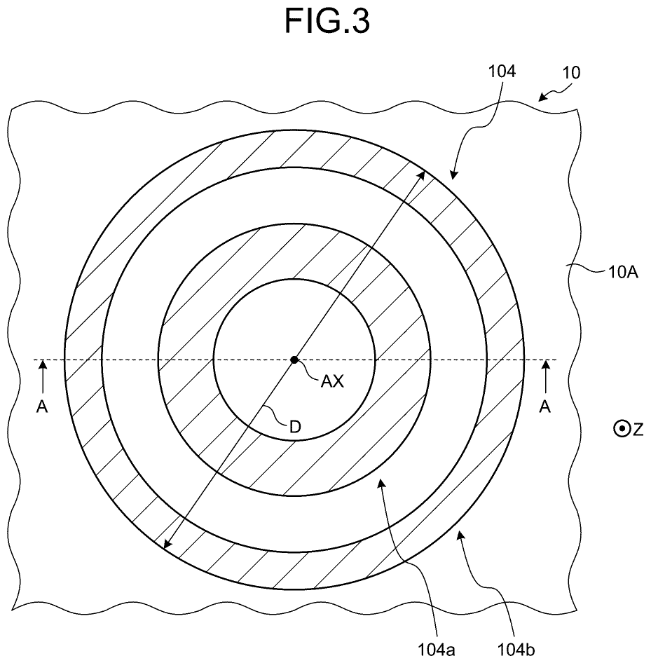

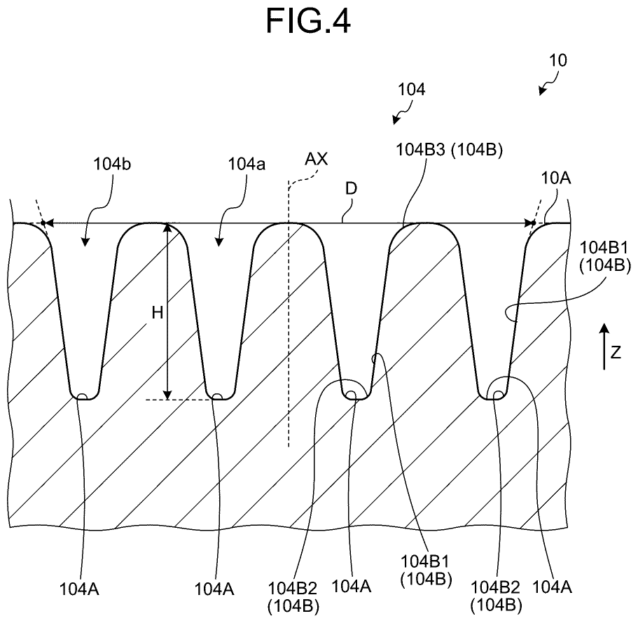

FIG. 3 is a schematic enlarged view of a portion of the glass substrate where the dot is formed, and FIG. 4 is an A-A cross-sectional view of FIG. 3. It can be said that FIG. 4 is a cross-sectional view of the glass substrate 10 assuming that a cross section is a plane PL passing through the center of the dot 104 and extending along the Z-direction. The dot 104 indicates an indentation formed on the surface 10A of the glass substrate 10. However, a dot shape is not necessarily an indentation shape, that is, a concave shape. For example, the dot shape is a convex shape in a case of being formed by printing, and in a case in which the dot is formed by sand blasting and the like, surface roughness of a corresponding point is increased and visibility of the mark is improved. In the present embodiment, the dot 104 is formed by irradiating the surface 10A with laser light. That is, it can be said that the dot 104 in the present embodiment is a laser irradiation trace (irradiation trace of laser light). One dot 104 may be formed of a plurality of laser irradiation traces, or may be formed of one laser irradiation trace. The laser light may be emitted to the same point multiple times to cause a depth of the dot after the machining to be easily read, or may be emitted while being shifted at a fixed pitch to form the dot. One laser irradiation trace indicates an irradiation trace formed by one shot of laser light. That is, the dot 104 may be formed by laser light emitted in one period from when the laser light is output until it is stopped, or may be formed by a plurality of laser irradiation traces. That is, the dot 104 may be formed by laser light that has been intermittently emitted over a plurality of periods.

### Shape of Dot

The following describes an example of the shape of the dot 104. However, the shape of the dot 104 is not limited to the following description, and may be optional.

As illustrated in FIG. 3, the dot 104 has a double-circle shape when viewed from the Z-direction. In FIG. 3, for convenience of explanation, depressed regions of the dot 104 are indicated by oblique lines. However, the shape of the dot 104 when viewed from the Z-direction is not limited to the double-circle shape. For example, the dot 104 may have a circular shape or the like when viewed from the Z-direction. Alternatively, the shape of the dot 104 may be a ring, a rectangle, an imperfect circle such as a character “C”, or a spiral shape obtained by combining a plurality of laser irradiation traces.

As illustrated in FIG. 4, the dot 104 includes a first indentation 104a as a portion depressed from the surface 10A of the glass substrate 10, and a second indentation 104b as a portion depressed from the surface 10A of the glass substrate 10 radially outside the first indentation 104a. The first indentation 104a and the second indentation 104b each have a ring shape when viewed from the Z-direction. In other words, there are regions projecting from the first indentation 104a and the second indentation 104b on a radially inner side of the first indentation 104a and the second indentation 104b. The first indentation 104a and the second indentation 104b each have a bottom surface 104A and a side surface 104B. The bottom surface 104A indicates a bottom portion of each of the first indentation 104a and the second indentation 104b, and the side surface 104B indicates a side surface portion connecting the bottom surface 104A of each of the first indentation 104a and the second indentation 104b and the surface 10A of the glass substrate 10. The side surface 104B includes a side surface part 104B1, a connection part 104B2, and a connection part 104B3. The side surface part 104B1 is a portion forming a side surface of each of the first indentation 104a and the second indentation 104b. The connection part 104B2 is a portion formed at an end part of the side surface part 104B1 on the opposite side of the Z-direction, and has an R-shape connecting the bottom surface 104A and the side surface part 104B1. The connection part 104B3 is a portion formed at an end part of the side surface part 104B1 on the Z-direction side, and has an R-shape connecting the side surface part 104B1 and the surface 10A of the glass substrate 10. However, the side surface 104B does not necessarily include the connection parts 104B2 and 104B3 each having the R-shape. A connecting portion between the bottom surface 104A and the side surface part 104B1 and a connecting portion between the side surface part 104B1 and the surface 10A of the glass substrate 10 may have an edge shape (angular shape).

### Diameter of Dot

A diameter D of the dot 104 is preferably equal to or larger than 50 μm and equal to or smaller than 200 μm, more preferably equal to or larger than 80 μm and equal to or smaller than 150 μm, and even more preferably equal to or larger than 90 μm and equal to or smaller than 120 μm. By causing the diameter of the dot 104 to fall within this range, the size of one dot 104 can be relatively large, and the mark 100 can be appropriately visually recognized. As illustrated in FIG. 4, the diameter D of the dot 104 may indicate a diameter of a virtual circle that is formed by a curved surface along the side surface part 104B1 radially outside the second indentation 104b (corresponding to a side surface of a truncated cone) and a plane along the surface 10A intersecting with each other. In a case in which the dot 104 does not have a circular shape, the diameter D may be the longest distance between two points on an outer circumference of a virtual region formed by the surface along the side surface part 104B1 radially outside the second indentation 104b and the plane along the surface 10A intersecting with each other.

### Depth of Dot

A depth H of the dot 104 is preferably equal to or larger than 0.5 μm and equal to or smaller than 7.0 μm, more preferably equal to or larger than 0.5 μm and equal to or smaller than 5.0 μm, and even more preferably equal to or larger than 0.5 μm and equal to or smaller than 3.0 μm. By causing the depth H to fall within this range, a fracture of the glass substrate 10 starting from the dot 104 can be suppressed, and ease of reading can be secured. The depth H indicates a distance between the surface 10A and the bottom surface 104A in the Z-direction.

The depth H of the dot 104 is measured by the following method. Regarding the dots of the mark, a cross-sectional shape of an optional dot is measured by a laser microscope. Subsequently, the lowest point of the cross section is assumed to be S, and a difference between the surface 10A as a glass main surface and the lowest point S in the Z-direction is assumed to be the depth H. However, in a case of a form having a concave shape on a dot outer peripheral part as illustrated in FIG. 5, the depression of the dot outer peripheral part does not need to be taken into account as the lowest point. The depth H can be measured by OLS4000 manufactured by Olympus Corporation.

Assuming that ΔH indicates a deviation of the depth of the bottom surface part excluding a depression generated on a radially inner side of the bottom surface, ΔH is preferably equal to or smaller than 50% of the depth H, and more preferably equal to or smaller than 25% thereof.

### Parameter y

Regarding the glass substrate 10, a parameter y defined by the following expression (1) is preferably smaller than 1.4, more preferably smaller than 0.8, and even more preferably smaller than 0.5. By causing the parameter y to fall within this range, a crack starting from the mark 100 (dot 104) can be suppressed, and a fracture of the glass substrate 10 starting from the crack can be suppressed.

y=0.021·C−0.0034·Tg−0.012·ρ+0.020·E−2.814·λ−0.433·Ra+4.372 (1)

In the expression (1), C is an average thermal expansion coefficient (ppm/° C.) of the glass substrate 10 at 50° C. to 200° C., Tg is a glass transition temperature (° C.) of the glass substrate 10, ρ is a density (g/cm³) of the glass substrate 10, E is a Young's modulus (GPa) of the glass substrate 10, λ is a thermal conductivity (W/m.° C.) of the glass substrate 10, and Ra is arithmetic average roughness (nm) of the surface 10A of the glass substrate defined in JIS B 0601:2001.

### Average Thermal Expansion Coefficient C

The average thermal expansion coefficient C of the glass substrate 10 at 50° C. to 200° C. is preferably equal to or larger than 3 ppm/° C. and smaller than 12.1 ppm/° C., more preferably equal to or larger than 3.0 ppm/° C. and smaller than 8.7 ppm/° C., and even more preferably equal to or larger than 3.0 ppm/° C. and smaller than 5.8 ppm/° C. By causing the average thermal expansion coefficient C to fall within this range, a crack can be prevented from being caused by local expansion of the glass substrate 10 due to heat absorption at the time of processing the dot 104.

The average thermal expansion coefficient C can be measured according to the method defined in JIS R3102 (1995). Specifically, a sample may be measured in a range from 30° C. to 300° C. using DIL 402 manufactured by NETZSCH Japan K.K. as a differential thermal expansion meter, and an average thermal expansion coefficient in a range from 50° C. to 200° C. may be caused to be the average thermal expansion coefficient C. A numerical range represented by “to” means a numerical range including numerical values before and after “to” as a lower limit value and an upper limit value, and the same applies to a case of using “to” hereinafter.

### Average Thermal Expansion Coefficient C_{cal}

The average thermal expansion coefficient C described above is a measured value of an average thermal expansion coefficient of the glass substrate 10. On the other hand, assuming that a calculated value of the average thermal expansion coefficient of the glass substrate 10 calculated from composition is the average thermal expansion coefficient C_{cal}, the average thermal expansion coefficient C_{cal} is preferably equal to or larger than 3.0 ppm/° C. and smaller than 12.2 ppm/° C., more preferably equal to or larger than 3.0 ppm/° C. and smaller than 8.7 ppm/° C., and even more preferably equal to or larger than 3.0 ppm/° C. and smaller than 5.8 ppm/° C. By causing the average thermal expansion coefficient Coal to fall within this range, a crack can be prevented from being caused by local expansion of the glass substrate 10 due to heat absorption at the time of processing the dot 104.

The following describes the average thermal expansion coefficient C_{cal}. Hereinafter, a content of oxide XOn of an element X contained in the glass substrate 10 is represented as [XOn] in mol % on an oxide basis. In this case, the average thermal expansion coefficient C_{cal} is assumed to be a value calculated by the following expression (2).

$${C}_{cal} = - 0.3 \; 03 \cdot [ Si {O}_{2} ] - 0.338 \cdot [ {Al}_{2} {O}_{3} ] - 0.3 \; 03 \cdot [ {B}_{2} {O}_{3} ] - 0.208 \cdot [ {P}_{2} {O}_{5} ] - 0.198 \cdot [ MgO ] - 0.2 \; 25 \cdot [ CaO ] - 0.1 \; 33 \cdot [ SrO ] - 0.104 \cdot [ BaO ] + 0.0 \; 71 \cdot [ {Na}_{2} O ] + 0.0 \; 77 \cdot [ {K}_{2} O ] + 32 \text{.548} \qquad ( 2 )$$

The glass substrate 10 does not necessarily contain all oxides included in the expression (2). In this case, a value of a right side of the expression (2) is assumed to be zero for an oxide that is included in the expression (2) but not contained in the glass substrate 10. That is, for example, in a case in which the glass substrate 10 does not contain SrO, the average thermal expansion coefficient C_{cal} is calculated assuming that [SrO] in the expression (2) is zero. The same applies to the following expressions.

### Glass Transition Temperature Tg

The Glass Transition Temperature Tg of the Glass substrate 10 is preferably equal to or higher than 500° C. and equal to or lower than 800° C., more preferably equal to or higher than 560° C. and equal to or lower than 800° C., and even more preferably equal to or higher than 714° C. and lower than 750° C. By causing the average thermal expansion coefficient C to fall within this range, a stable structure against impact at the time of processing the dot 104 can be obtained, and generation of a crack can be suppressed.

The glass transition temperature Tg can be measured according to the method defined in JIS R3103-3 (2001).

### Glass Transition Temperature Tg_{cal}

The glass transition temperature Tg described above is a measured value of a glass transition temperature of the glass substrate 10. On the other hand, assuming that a calculated value of the glass transition temperature of the glass substrate 10 calculated from the composition is the glass transition temperature Tg_{cal}, the glass transition temperature Tg_{cal} is preferably equal to or higher than 500° C. and equal to or lower than 800° C., more preferably equal to or higher than 561° C. and equal to or lower than 800° C., and even more preferably equal to or higher than 712° C. and lower than 741° C. By causing the glass transition temperature Tg_{cal} to fall within this range, a stable structure against impact at the time of processing the dot 104 can be obtained, and generation of a crack can be suppressed.

The glass transition temperature Tg_{cal} is calculated by the following expression (3).

$${Tg}_{cal} = - 3218 \cdot [ Si {O}_{2} ] - 24 [ {Al}_{2} {O}_{3} ] - \text{} [ {B}_{2} {O}_{3} ] - 4 \; 0.1 \cdot [ MgO ] - 40.809 \cdot [ CaO ] - 37.1 \; 05 \cdot [ SrO ] - 39.031 \cdot [ BaO ] - 46.1 \; 25 \cdot [ {Na}_{2} O ] - 52.2 \; 47 \cdot [ {K}_{2} O ] + 4489.419 \qquad ( 3 )$$

### Density ρ

The density ρ of the glass substrate 10 is preferably equal to or larger than 2.4 g/cm³ and equal to or smaller than 3.5 g/cm³, more preferably equal to or larger than 2.4 g/cm³ and smaller than 3.5 g/cm³, and even more preferably equal to or larger than 2.4 g/cm³ and smaller than 2.8 g/cm³. By causing the density ρ to fall within this range, an amount of energy applied to the glass substrate 10 to process the dot 104 is not required to be excessive, and generation of a crack can be suppressed.

The density ρ can be measured by the Archimedes method.

### Density ρ_{cal}

The density ρ described above is a measured value of the density of the glass substrate 10. On the other hand, assuming that a calculated value of the density of the glass substrate 10 calculated from the composition is the density ρ_{cal}, the density ρ_{cal} is preferably equal to or larger than 2.4 g/cm³ and equal to or smaller than 3.5 g/cm³, more preferably equal to or larger than 2.4 g/cm³ and smaller than 3.5 g/cm³, and even more preferably equal to or larger than 2.4 g/cm³ and smaller than 2.8 g/cm³. By causing the density ρ_{cal} to fall within this range, an amount of energy applied to the glass substrate 10 to process the dot 104 is not required to be excessive, and generation of a crack can be suppressed.

The density ρ_{cal} is calculated by the following expression (4).

$${ρ}_{cal} = - 0.0 \; 07 \cdot [ {SiO}_{2} ] - 0 \text{.01} \cdot [ {Al}_{2} {O}_{3} ] - 0.0 \; 06 \cdot [ {B}_{2} {O}_{3} ] + 0. 06 \cdot [ MgO ] + 0 \text{.008} \cdot [ CaO ] + 0.0 \; 21 \cdot [ SrO ] + 0.038 \cdot [ BaO ] - 0.003 \cdot [ {Na}_{2} O ] + 0.0 \; 01 \cdot [ {K}_{2} O ] + 2.931 \qquad ( 4 )$$

### Young's Modulus E

The Young's modulus E of the glass substrate 10 is preferably larger than 70 GPa, and more preferably larger than 78 GPa. By causing the Young's modulus E to fall within this range, generation of a crack can be suppressed.

The Young's modulus E can be measured based on an ultrasonic pulse method using 38DL PLUS manufactured by Olympus Corporation.

Young's modulus E_{cal}

The Young's modulus E described above is a measured value of the Young's modulus of the glass substrate 10. On the other hand, assuming that a calculated value of the Young's modulus of the glass substrate 10 calculated from the composition is the Young's modulus E_{cal}, the Young's modulus E_{cal} is preferably larger than 70 GPa, and more preferably larger than 78 GPa. By causing the Young's modulus E_{cal} to fall within this range, generation of a crack can be suppressed.

The Young's modulus E_{cal} can be calculated based on the following expression (5).

$${E}_{cal} = 1.6 \; 35 \cdot [ Si {O}_{2} ] + 2.428 \cdot [ {Al}_{2} {O}_{3} ] + 0.9 \; 24 \cdot [ {B}_{2} {O}_{3} ] + 2.227 \cdot [ MgO ] + 2.3 \; 11 \cdot [ CaO ] + 1.3 \; 59 \cdot [ SrO ] + 1.861 \cdot [ BaO ] + 1.127 \cdot [ {Na}_{2} O ] + 1.6 \; 46 \cdot [ {K}_{2} O ] - 94.916 \qquad ( 5 )$$

### Thermal Conductivity A

The thermal conductivity λ of the glass substrate 10 is preferably larger than 0.8 W/m.° C., preferably larger than 0.8 W/m.° C. and smaller than 1.4 W/m.° C., more preferably larger than 0.9 W/m.° C. and smaller than 1.1 W/m.° C., and even more preferably equal to or larger than 1.0 W/m.° C. and smaller than 1.1 W/m.° C. By causing the thermal conductivity A to fall within this range, heat generated at the time of processing the dot 104 is appropriately transferred to the surroundings, and a crack caused by local heating can be suppressed.

The thermal conductivity A can be measured according to the method defined in JIS R3102 (1995). Specifically, a sample may be measured in a range from 30° C. to 300° C. using a differential thermal expansion meter, and an average value of the thermal conductivity in a range from 50° C. to 200° C. may be caused to be the thermal conductivity A.

Thermal conductivity λ_{cal}

The thermal conductivity λ described above is a measured value of the thermal conductivity of the glass substrate 10. On the other hand, assuming that a calculated value of the thermal conductivity of the glass substrate 10 calculated from the composition is the thermal conductivity λ_{cal}, the thermal conductivity λ_{cal} is preferably larger than 0.8 W/m.° C., preferably larger than 0.8 W/m.° C. and smaller than 1.4 W/m.° C., more preferably larger than 0.8 W/m.° C. and smaller than 1.1 W/m.° C., and even more preferably larger than 0.8 W/m.° C. and equal to or smaller than 1.0 W/m.° C. By causing the thermal conductivity λ_{cal} to fall within this range, heat generated at the time of processing the dot 104 is appropriately transferred to the surroundings, and a crack caused by local heating can be suppressed.

The thermal conductivity λ_{cal} can be calculated based on the following expression (6).

$${λ}_{cal} = - 0.0 \; 26 \cdot [ Si {O}_{2} ] - 0 \text{.03} \cdot [ {Al}_{2} {O}_{3} ] - 0.032 \cdot [ {B}_{2} {O}_{3} ] - 0. 16 \cdot [ MgO ] - 0 \text{.008} \cdot [ CaO ] + 0.0 \; 11 \cdot [ SrO ] - 0.057 \cdot [ BaO ] - 0. 22 \cdot [ {Na}_{2} O ] - 0.0 \; 44 \cdot [ {K}_{2} O ] + 3.502 \qquad ( 6 )$$

### Arithmetic Average Roughness Ra

The arithmetic average roughness Ra of the surface 10A of the glass substrate 10 described above may indicate the arithmetic average roughness Ra at an optional position on the surface 10A. For example, the arithmetic average roughness Ra of the surface 10A of the glass substrate 10 may be the arithmetic average roughness Ra of a region (peripheral region) around the mark 100 (dot 104) in a region in which the dot 104 is not formed (in this example, a region in which the first indentation 104a and the second indentation 104b are not formed). The region (peripheral region) around the mark 100 (dot 104) may be a region (peripheral region) within 5 mm from the dot 104 in the region in which the dot 104 is not formed on the surface 10A. The arithmetic average roughness Ra of this peripheral region is preferably equal to or larger than 0.3 nm and smaller than 1.7 nm, more preferably larger than 0.5 nm and smaller than 1.7 nm, even more preferably larger than 0.6 nm and smaller than 1.7 nm, and yet more preferably larger than 0.6 nm and equal to or smaller than 0.9 nm. By causing the arithmetic average roughness Ra around the dot 104 on the surface 10A to fall within this range, energy at the time of processing the dot 104 is appropriately absorbed by the surface 10A, and generation of a crack can be suppressed. The arithmetic average roughness Ra is measured according to specifications of JIS B 0601:2001. The arithmetic average roughness Ra may be measured by OLS4000 manufactured by Olympus Corporation at 50-fold magnification of an object lens.

The arithmetic average roughness Ra of the surface 10A described above may be the arithmetic average roughness Ra of a region in which the dot 104 is formed (in this example, a region in which the first indentation 104a and the second indentation 104b are formed).

The arithmetic average roughness Ra of a region outside the peripheral region (radially outside the peripheral region) of the dot 104 on the surface 10A of the glass substrate 10 may be smaller or larger than the above-described preferable range of the arithmetic average roughness Ra of the peripheral region. For example, for a use in a high-definition device, the arithmetic average roughness Ra of the region outside the peripheral region on the surface 10A of the glass substrate 10 may be preferably equal to or smaller than 0.5 nm, more preferably smaller than 0.5 nm, even more preferably equal to or smaller than 0.3 nm, and yet more preferably smaller than 0.3 nm, and the arithmetic average roughness Ra of the peripheral region may be designed to fall within the preferable range described above. Specifically, for a use in a glass substrate for an image sensor, by causing the arithmetic average roughness Ra of the region outside the peripheral region on the surface 10A to be 0.3 nm, and causing Ra of the peripheral region to be 1.0 nm, Ra of the region used as a substrate can be favorably maintained while facilitating laser machining.

### Composition

The composition of the glass substrate 10 may be optional so long as the parameter y falls within the range described above. The following describes an example of the composition of the glass substrate 10.

For example, the glass substrate 10 may contain the following compounds in mass % (wt %) on an oxide basis.

SiO₂: preferably equal to or larger than 40% and equal to or smaller than 70%, and preferably equal to or larger than 50% and equal to or smaller than 65%.

Al₂O₃: preferably equal to or larger than 0 wt % and equal to or smaller than 25 wt %, and more preferably equal to or larger than 5 wt % and equal to or smaller than 25 wt %.

B₂O₃: preferably equal to or larger than 0 wt % and equal to or smaller than 20 wt %, and more preferably equal to or larger than 0 wt % and equal to or smaller than 15 wt %.

MgO: preferably equal to or larger than 0 wt % and equal to or smaller than 20 wt %, and more preferably equal to or larger than 0 wt % and equal to or smaller than 15 wt %.

CaO: preferably equal to or larger than 0 wt % and equal to or smaller than 25 wt %, and more preferably equal to or larger than 1 wt % and equal to or smaller than 15 wt %.

SrO: preferably equal to or larger than 0 wt % and equal to or smaller than 25 wt %, and more preferably equal to or larger than 0 wt % and equal to or smaller than 15 wt %.

BaO: preferably equal to or larger than 0 wt % and equal to or smaller than 40 wt %, and more preferably equal to or larger than 0 wt % and equal to or smaller than 30 wt %.

Na₂O: preferably equal to or larger than 0 wt % and equal to or smaller than 20 wt %, and more preferably equal to or larger than 0 wt % and equal to or smaller than 15 wt %.

K₂O: preferably equal to or larger than 0 wt % and equal to or smaller than 15 wt %.

### Method for Manufacturing Glass Substrate

A method for manufacturing the glass substrate 10 in the present embodiment includes: a preparation step of preparing a glass plate as the glass substrate before the mark 100 is formed; and an irradiation step of irradiating the surface of the glass plate with laser light to form the mark 100, and manufacturing the glass substrate 10. At the preparation step, after melting a glass raw material, the glass plate is manufactured by causing the glass raw material to be in a glass state by an optional glass molding method such as a float method, a fusion method, or an ingot forming method, and the glass plate is processed to have the shape of the glass substrate thereafter. In the example of the present embodiment, the glass substrate has a disc shape, so that the glass is cut out in a circular shape by optional means such as slicing and circular shape cutting, for example, to form the glass plate having a circular shape. The glass plate cut out in the circular shape is subjected to chamfering processing for an end face and grinding and polishing processing for a surface. Herein, when Ra in the vicinity of the region in which the dot is formed deviates from a preferable range, additional processing can be performed on a target region. That is, at an optional timing after the grinding and polishing processing of the surface and before machining with a laser, surface treatment such as additional local polishing or chemical solution processing can be performed on the target region. Examples of local polishing include additional polishing performed on a region in the vicinity of an engraved seal using a polishing pad including a small head, or fine processing of the surface with a chemical solution such as hydrofluoric acid, a laser, or plasma. By performing such local processing, the dot 104 can be formed by laser machining on the glass substrate on which laser machining is hardly performed. The glass plate that has been subjected to the designed steps is further subjected to a cleaning and inspecting step to have desired Ra, and the preparation step is completed. At the irradiation step, processing of forming the dot 104 by irradiating the surface of the glass plate with laser light is repeatedly performed to form the mark 100 constituted of a plurality of the dots 104 on the surface of the glass plate. At the time of emitting laser light, a metal film or a resin film having a high absorption coefficient may be applied to facilitate laser machining or prevent attachment of scattered matter.

At the irradiation step, the dot 104 is formed by irradiating the glass surface with laser light. For example, by using a light source having a wavelength of 532 nm, the laser light is emitted to the glass surface via various optical appliances from the light source. A spot diameter may be adjusted by an optical system so that a dot diameter is about 100 μm. The glass surface is moved in an xy-direction by using a scanner, but an xy stage or the like may be used.

### Effects

As described above, in the glass substrate 10 according to a first aspect of the present disclosure, the mark 100 is provided on the surface 10A, and the parameter y defined by the expression (1) is smaller than 1.4.

At the time of forming the mark, a crack starting from the mark may be caused, and a fracture of the glass substrate starting from the crack may be caused. On the other hand, as a result of vigorous investigation, the present inventors have found that generation of a crack is related to the average thermal expansion coefficient C, the glass transition temperature Tg, the density p, the Young's modulus E, the thermal conductivity A, and the arithmetic average roughness Ra (surface roughness) of the surface 10A, and a crack can be suppressed by causing the parameter y to fall within a predetermined range. That is, with the glass substrate 10 according to the present embodiment, generation of a crack starting from the mark can be suppressed by causing the parameter y to be smaller than 1.4, and as a result, a fracture can be suppressed.

The glass substrate 10 according to a second aspect of the present disclosure is the glass substrate 10 according to the first aspect in which the arithmetic average roughness Ra defined in JIS B 0601:2001 around the mark on the surface 10A of the glass substrate 10 is preferably equal to or larger than 0.3 nm and smaller than 1.7 nm. By causing the arithmetic average roughness Ra to fall within this range, generation of a crack can be more preferably suppressed.

The glass substrate 10 according to a third aspect of the present disclosure is the glass substrate 10 according to the first aspect or the second aspect in which the average thermal expansion coefficient of the glass substrate 10 at 50° C. to 200° C. is preferably equal to or larger than 3 ppm/° C. and smaller than 12.1 ppm/° C. By causing the average thermal expansion coefficient to fall within this range, generation of a crack can be more preferably suppressed.

The glass substrate 10 according to a fourth aspect of the present disclosure is the glass substrate 10 according to any one of the first aspect to the third aspect in which the glass transition temperature of the glass substrate 10 is preferably equal to or higher than 500° C. and equal to or lower than 800° C. By causing the glass transition temperature to fall within this range, generation of a crack can be more preferably suppressed.

The glass substrate 10 according to a fifth aspect of the present disclosure is the glass substrate 10 according to any one of the first aspect to the fourth aspect in which the density of the glass substrate 10 is preferably equal to or larger than 2.4 g/cm³ and equal to or smaller than 3.5 g/cm³. By causing the density to fall within this range, generation of a crack can be more preferably suppressed.

The glass substrate 10 according to a sixth aspect of the present disclosure is the glass substrate 10 according to any one of the first aspect to the fifth aspect in which the Young's modulus of the glass substrate 10 is preferably equal to or larger than 71 GPa. By causing the Young's modulus to fall within this range, generation of a crack can be more preferably suppressed.

The glass substrate 10 according to a seventh aspect of the present disclosure is the glass substrate 10 according to any one of the first aspect to the sixth aspect in which the thermal conductivity of the glass substrate 10 is preferably larger than 0.8 W/m.° C. By causing the thermal conductivity to fall within this range, generation of a crack can be more preferably suppressed.

The glass substrate 10 according to an eighth aspect of the present disclosure is the glass substrate 10 according to any one of the first aspect to the seventh aspect in which the deviation of the thickness is preferably equal to or smaller than 3 μm. By causing the deviation of the thickness to fall within this range, a device and the like can be appropriately supported.

The glass substrate 10 according to a ninth aspect of the present disclosure is the glass substrate 10 according to any one of the first aspect to the eighth aspect that has a disc shape with a diameter equal to or smaller than 300 mm and a thickness equal to or larger than 0.3 mm and equal to or smaller than 2.0 mm, and the notch part N may be formed on the outer peripheral surface.

The glass substrate 10 according to a tenth aspect of the present disclosure is the glass substrate 10 according to any one of the first aspect to the eighth aspect, and may have a rectangular plate shape with a thickness equal to or larger than 0.5 mm and equal to or smaller than 2.0 mm in which a maximum value of a distance between optional two points on the outer peripheral edge is equal to or larger than 300 mm and equal to or smaller than 1000 mm. By causing the glass substrate 10 to have such a shape, a device and the like can be appropriately supported.

Herein, of the entire region of the glass substrate 10, a region between a position at a distance of 1 mm radially inward from a peripheral edge and a position at a distance of 5 mm radially inward from the peripheral edge is assumed to be an outer side region. Of the entire region of the glass substrate 10, a region surrounded by a square each side of which is 100 mm centered on a center point O of the glass substrate 10 is assumed to be a center side region. In this case, an average value of a thickness D of the glass substrate 10 in the outer side region may be larger than an average value of the thickness D of the glass substrate 10 in the center side region (that is, the center part may be thicker). In contrast, the average value of the thickness D of the glass substrate 10 in the outer side region may be smaller than the average value of the thickness D of the glass substrate 10 in the center side region (that is, the center part may be thinner). A deviation of the thickness D in the entire region of the glass substrate 10 is preferably equal to or smaller than 1 μm, and more preferably equal to or smaller than 0.5 μm.

The deviation of the thickness in only the outer side region of the glass substrate 10 is preferably 1 μm, and more preferably equal to or smaller than 0.5 μm. The deviation of the thickness in only an inner side region of the glass substrate 10 is preferably 1 μm, and more preferably equal to or smaller than 0.5 μm. With the glass substrate 10 in which plate thickness deviations in the outer side region and the inner side region are small, each process can stably flow. By applying the glass substrate 10 the center part of which is thin, processes such as adsorption or deposition can stably flow.

As a manufacturing method for implementing a shape the center part of which is thin or thick as described above, for example, it is considered that a pressure at the center of the glass substrate 10 or a relative velocity of polishing fabric may be increased in physical processing such as polishing. For example, in hydrofluoric acid (HF) etching, to selectively etch the center of the glass substrate 10, it is considered that the outer peripheral part may be masked, the center part of the glass substrate 10 may be heated, and a chemical solution flow channel may be adjusted so that a fresh chemical solution always hits the center part of the glass substrate 10.

In a case of supporting the glass substrate at three points, sizes of WARP and BOW of the glass substrate 10 are preferably equal to or smaller than 200 μm, and more preferably equal to or smaller than 100 μm. WARP and BOW of the glass substrate 10 are preferably aligned when being used for a semiconductor process.

The glass substrate 10 may include a mark for direction identification. The mark is implemented at only one point on the outer peripheral part of the glass substrate 10. However, marks may be present at two or more points for managing a direction, or the mark may be present at the center part of the glass substrate 10. In a case of a rectangular substrate, marks may be present at one or more points at asymmetrical positions in a plane. In a case of a wafer shape without a notch, or a case of a rectangular shape, which is a square shape, a direction in an xy-plane is unclear. However, by applying a mark having a function as an alignment mark to the glass substrate 10, orientation of BOW or a direction in the xy-plane can be managed. In a case of the rectangular substrate, corners may be asymmetrically cut to have acute angles or obtuse angles to manage the direction, and glass that is cut is at risk of breakage when held at an apex. By forming alignment marks at one or more points on the glass substrate 10, shapes of the respective corners can be symmetrical shapes with a corner R. R of the corner is preferably equal to or larger than 0 mm and equal to or smaller than 20 mm, and more preferably equal to or larger than 5 mm and equal to or smaller than 15 mm.

The outer peripheral part of the glass substrate 10 is preferably subjected to chamfering processing. The outer peripheral part is preferably further subjected to mirror finishing. The arithmetic average roughness Ra of the outer peripheral part is preferably equal to or smaller than 0.1 μm, and more preferably equal to or smaller than 0.05 μm. The outer peripheral part is processed so that a notch may be made in a case of an end face, a chamfered part, and a circular substrate, and all corner parts have the same surface roughness in a case of a rectangular substrate. However, only part of the outer circumference, a notch portion, and the corner part may be processed to have large surface roughness to adjust a deposition condition or improve accuracy of end face detection.

The glass substrate 10 according to an eleventh aspect of the present disclosure is the glass substrate according to any one of the first aspect to the tenth aspect, and is preferably used as the glass substrate supporting the semiconductor device. The glass substrate 10 according to the present embodiment can appropriately support the semiconductor device.

The glass substrate 10 according to a twelfth aspect of the present disclosure is the glass substrate 10 according to any one of the first aspect to the eleventh aspect in which the arithmetic average roughness Ra defined in JIS B 0601:2001 on the outer side from the surroundings of the mark on the surface 10A of the glass substrate 10 is preferably equal to or smaller than 0.3 nm. By causing the surface roughness on the outer side from the surroundings of the mark to be small in this way, a breakage can be appropriately suppressed.

### EXAMPLES

Next, the following describes examples. Table 1 is a table indicating the examples.

TABLE 1

| | | Exam- | Exam- | Exam- | Exam- | Exam- | Exam- | Exam- | Exam- | Exam- | Exam- |
|---|---|---|---|---|---|---|---|---|---|---|---|
| | | ple 1 | ple 2 | ple 3 | ple 4 | ple 5 | ple 6 | ple 7 | ple 8 | ple 9 | ple 10 |
| Con- | Thermal expansion coefficient C [ppm/K] | 3.6 | 4.8 | 3.2 | 3.3 | 5.8 | 8.2 | 8.7 | 9.5 | 12.1 | 5.1 |
| dition | (measured value) | | | | | | | | | | |
| | Thermal expansion coefficient Ccal [ppm/K] | 3.6 | 4.9 | 3.3 | 3.4 | 5.8 | 8.3 | 8.7 | 9.4 | 12.2 | 5.2 |
| | (calculated value) | | | | | | | | | | |
| | Thermal conductivity λ [W/m · K] | 1.0 | 0.9 | 1.0 | 1.2 | 1.0 | 0.7 | 1.1 | 0.9 | 0.8 | 1.3 |
| | (measured value) | | | | | | | | | | |
| | Thermal conductivity λcal [W/m · K] | 1.1 | 0.9 | 1.1 | 1.1 | 1.0 | 0.7 | 1.1 | 1.0 | 0.8 | 1.3 |
| | (calculated value) | | | | | | | | | | |
| | Glass transition temperature Tg [° C.] | 710 | 690 | 754 | 723 | 750 | 714 | 560 | 604 | 488 | 754 |
| | (measured value) | | | | | | | | | | |
| | Glass transition temperature Tgcal [° C.] | 718 | 687 | 760 | 722 | 742 | 712 | 561 | 597 | 493 | 751 |
| | (calculated value) | | | | | | | | | | |
| | Density ρ [g/cm³] (measured value) | 2.5 | 2.8 | 2.5 | 2.5 | 3.0 | 3.5 | 2.5 | 2.5 | 2.8 | 2.7 |
| | Density ρcal [g/cm³] (calculated value) | 2.5 | 2.8 | 2.4 | 2.5 | 3.0 | 3.5 | 2.5 | 2.4 | 2.8 | 2.7 |
| | Young's modulus E [GPa] (measured value) | 76 | 76 | 85 | 75 | 75 | 78 | 73 | 74 | 70 | 100 |
| | Young's modulus Ecal [GPa] | 77 | 75 | 85 | 74 | 75 | 78 | 73 | 75 | 70 | 100 |
| | (calculated value) | | | | | | | | | | |
| | Arithmetic average roughness Ra (nm) | 0.6 | 0.6 | 0.8 | | 0.7 | 0.9 | 0.6 | 0.9 | 1.7 | 0.7 |
| | polishing condition 1 | | | | | | | | | | |
| | Arithmetic average roughness Ra (nm) | 0.3 | 0.5 | 0.3 | 0.3 | 0.3 | 0.5 | 0.5 | 0.5 | 0.6 | |
| | polishing condition 2 | | | | | | | | | | |
| | Parameter y | 0.4 | 0.8 | 0.4 | 0.2 | 0.3 | 1.2 | 0.7 | 1.0 | 1.4 | −0.2 |
| | polishing condition 1 | | | | | | | | | | |
| | Parameter y | 0.6 | 0.8 | 0.5 | 0.1 | 0.5 | 1.3 | 0.8 | 1.2 | 1.9 | |
| | polishing condition 2 | | | | | | | | | | |
| Evalu- | Crack generation rate | 0.0% | 0.0% | 0.0% | | 0.0% | 0.3% | 0.0% | 0.0% | 6.2% | 0.0% |
| ation | polishing condition 1 | | | | | | | | | | |
| | Crack generation rate | 0.1% | 0.2% | 0.1% | 0.1% | 0.6% | 1.0% | 1.1% | 0.7% | 5.5% | 0.0% |
| | polishing condition 1 | | | | | | | | | | |

In the respective examples, as indicated by Table 1, glass plates that were different in a physical property and surface roughness were prepared, and a glass substrate having a diameter of 300 mm and a thickness of 1.0 mm was prepared. For glass substrates having the same physical property, samples polished under different polishing conditions (a polishing condition 1, a polishing condition 2) were prepared.

For the glass substrate in each of the examples, the average thermal expansion coefficient C, the glass transition temperature Tg, the density p, the Young's modulus E, the thermal conductivity A, and the arithmetic average roughness Ra of the surface were measured. As a measurement condition, the method described in the above embodiment was used. Table 1 indicates measurement results of the respective examples. The arithmetic average roughness Ra is a measured value in the peripheral region in a range at a distance of 5 mm from the dot.

For the glass substrate in each of the examples, the average thermal expansion coefficient C_{cal}, the glass transition temperature Tg_{cal}, the density ρ_{cal}, the Young's modulus E_{cal}, and the thermal conductivity λ_{cal} were calculated based on the composition. As a calculation condition, the method described in the above embodiment was used. Table 1 indicates calculation results of the respective examples.

For the glass substrate in each of the examples, the parameter y was calculated based on the measured average thermal expansion coefficient C, glass transition temperature Tg, density ρ, Young's modulus E, thermal conductivity λ, and arithmetic average roughness Ra of the surface. Table 1 indicates values of the parameter y of the respective examples. The value of the arithmetic average roughness Ra was different depending on the polishing condition, so that the arithmetic average roughness Ra and the parameter y were measured and calculated for each of the polishing conditions.

### Evaluation

The surface of the glass substrate in each of the examples was irradiated with laser light at a wavelength of 532 nm multiple times to form dots each having a double circle shape. The number of the dots formed on one glass substrate was 1300 to 2500.

In evaluation, presence/absence of a crack starting from each dot was observed. Specifically, when the surface of the glass substrate 10 in each example was observed by visual inspection at 50-fold magnification using a microscope (laser microscope manufactured by KEYENCE CORPORATION), it is determined that a crack was present in a case in which there was a crack having a length equal to or larger than 10 μm starting from the dot, and it is determined that a crack was absent in a case in which there was no crack having a length equal to or larger than 10 μm starting from the dot. By observing presence/absence of a crack for each of the dots formed on the glass substrate 10 in each example, a ratio of the number of the dots for which it is determined that a crack is present to a total number of the dots was calculated as a crack generation rate for each of the glass substrates 10 in the respective examples. Table 1 indicates the crack generation rate.

As indicated by Table 1, it is found that the crack generation rate of a certain sample exceeds 5% when the parameter y becomes equal to or larger than 1.4 as indicated by Example 9 as a comparative example, for example, but as indicated by Examples 1 to 8 and 10 as the examples, the crack generation rate is smaller than 5% in all samples having the parameter y smaller than 1.4. In this way, it is found that the crack generation rate can be caused to be smaller than 5%, and generation of a crack can be suppressed by causing the parameter y to be smaller than 1.4. As indicated by the examples, it is found that the crack generation rate tends to be increased when the arithmetic average roughness Ra is smaller than 0.3 nm, or equal to or larger than 1.7 nm, so that it is more preferable to cause the arithmetic average roughness Ra to be equal to or larger than 0.3 nm and smaller than 1.7 nm to maintain the crack generation rate to be low.

According to the present invention, a fracture starting from a mark on glass and from the surroundings of the mark can be suppressed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A glass substrate having a surface on which a mark is provided, wherein a parameter y defined by the following expression (1) is smaller than 1.4,
$$y = 0.0 \; 21 \cdot C - 0.0034 \cdot Tg - 0.012 \cdot ρ + 0.02 \cdot E - 2 \text{.814} \cdot λ - 0.433 \cdot Ra + 4.372 \qquad ( 1 )$$
where
C is an average thermal expansion coefficient (ppm/° C.) of the glass substrate at 50° C. to 200° C.,
Tg is a glass transition temperature (° C.) of the glass substrate,
ρ is a density (g/cm³) of the glass substrate,
E is a Young's modulus (GPa) of the glass substrate,
λ is a thermal conductivity (W/m.° C.) of the glass substrate, and
Ra is an arithmetic average roughness (nm) defined in JIS B 0601:2001 of the surface of the glass substrate.

2. The glass substrate according to claim 1, wherein the arithmetic average roughness Ra defined in JIS B 0601:2001 around the mark on the surface of the glass substrate is equal to or larger than 0.3 nm and smaller than 1.7 nm.

3. The glass substrate according to claim 1, wherein the average thermal expansion coefficient of the glass substrate at 50° C. to 200° C. is equal to or larger than 3 ppm/° C. and smaller than 12.1 ppm/° C.

4. The glass substrate according to claim 1, wherein the glass transition temperature of the glass substrate is equal to or higher than 500° C. and equal to or lower than 800° C.

5. The glass substrate according to claim 1, wherein the density of the glass substrate is equal to or larger than 2.4 g/cm³ and equal to or smaller than 3.5 g/cm³.

6. The glass substrate according to claim 1, wherein the Young's modulus of the glass substrate is equal to or larger than 71 GPa.

7. The glass substrate according to claim 1, wherein the thermal conductivity of the glass substrate is larger than 0.8 W/m.° C.

8. The glass substrate according to claim 1, wherein a deviation of a thickness is equal to or smaller than 3 μm.

9. The glass substrate according to claim 1 having a disc shape with a diameter equal to or smaller than 300 mm and a thickness equal to or larger than 0.3 mm and equal to or smaller than 2.0 mm, wherein a notch part is formed on an outer peripheral surface.

10. The glass substrate according to claim 1 having a rectangular plate shape, wherein a maximum value of a distance between two optional points on an outer peripheral edge is equal to or larger than 300 mm and equal to or smaller than 1000 mm, and a thickness is equal to or larger than 0.5 mm and equal to or smaller than 2.0 mm.

11. The glass substrate according to claim 1, used as a glass substrate for supporting a semiconductor device.

12. The glass substrate according to claim 1, wherein the arithmetic average roughness Ra defined in JIS B 0601:2001 on an outer side from surroundings of the mark on the surface of the glass substrate is equal to or smaller than 0.5 nm.
